(19) United States
(12) Patent Application Publication
(10) Pub. No.: US 2026/0226587 A1
(43) Pub. Date: Aug. 6, 2026

(54) PALLADIUM-BASED TERNARY OR HIGHER ALLOYS

(71) Applicant: Deringer-Ney Inc., Bloomfield, CT (US)

(72) Inventors: Grant G. Justice, Avon, CT (US); Patrick K. Bowen, Windsor, CT (US)

(21) Appl. No.: 19/443,529

(22) Filed: Jan. 8, 2026

Related U.S. Application Data
(60) Provisional application No. 63/752,315, filed on Jan. 31, 2025.

(51) Int. Cl. C22C 5/04; C22F 1/14; G01R 1/067

(52) U.S. Cl. CPC C22C 5/04; C22F 1/14; G01R 1/067

(57) ABSTRACT

An example palladium-based alloy includes a palladium-copper-silver alloy. Such an alloy may include palladium at about 50-57 weight percent (“wt %”), copper at about 35-42 wt %, and silver at about 3-7 wt %. The alloy may also include at least one of rhenium, zinc, gallium, indium, or any of the other elements disclosed herein. For instance, the alloy may include at least 0.5-2 wt % of at least one of rhenium, zinc, gallium, or indium. The alloy may exhibit at least one of a conductivity of 28% of the international annealed copper standard for electrical conductivity or greater, an ultimate tensile strength of 1.1 GPa or greater, a yield strength of about 825 MPa or greater, or a current that may be carried by a 250 μm wire of about 4 A or greater.

### CROSS REFERENCE TO RELATED APPLICATIONS

This application claims priority to U.S. Provisional Patent Application No. 63/752,315, filed Jan. 31, 2025, entitled “PALLADIUM-BASED TERNARY OR HIGHER ALLOYS,” which is incorporated by reference herein, in the entirety and for all purposes.

### BACKGROUND

In the field of semiconductor manufacturing there is a continuing demand for smaller device sizes (i.e., higher transistor counts per unit area) and increased processing power (i.e., faster processing speeds).

Because of their desirable resistance to oxidation, the use of precious metal alloys for stationary and moveable (i.e., reciprocating or sliding) electrical contacts as well as test probes enjoys widespread use for applications such as slip ring brushes, semiconductor probes, potentiometric sensors, etc. For the past 60 years, Paliney® 7 has been recognized as the benchmark alloy for applications requiring excellent oxidation resistance and formability in its fully age hardened condition. However, its electrical conductivity is very low, being only about 5.5% of the international annealed copper standard (“IACS”) for electrical conductivity.

U.S. Pat. No. 5,833,774 to Klein et al. discloses compositions of silver/palladium/copper alloys which are used in such applications and describes a range of noble metal alloys, which when heat treated, can offer a range of hardness levels with electrical conductivity in a range of 12-16% IACS. Even though commercial alloys consistent with this teaching (Paliney™ H3C and Paliney™ C) have conductivity values that are nearly three times that of Paliney 7 (see Table 2), they still fall short of the desired current-carrying capacity of many new applications. For example, for integrated circuit (IC) test probes with diameters below 100 microns, current levels that can be successfully used remain below 2 Amps because of excessive electrical heating (“New Generation of Probe Alloys”, Smith, et. Al., IEEE SW Test Workshop, June 2013). Another shortcoming of alloys within this family is their difficulty in being formed into complex, highly tolerance shapes when in the fully age-hardened condition.

U.S. Pat. No. 6,210,636 to Klein discloses a low-cost silver/palladium/copper/nickel/zinc high strength alloy suitable for sliding electrical contact applications. However, because this alloy was developed to reduce its noble metal content and resultant cost by increasing its nickel and zinc content, its oxidation resistance is poor in comparison to alloys having higher noble metal contents. Additionally, for these alloys, the overall conductivity is generally below 10% IACS (Paliney™ M5, DNI website).

Although alloys in the Pd—Cu—Ag family have been studied since the 1950's (Raub and Worwag, Z. Metallkd., 1955, 46, 52-57), most of the published work has focused on documenting the possible phase relationships and establishing the effect of several different solid state phase transformations on the electrical properties of the alloys. Amongst these solid state reactions, long-range ordering reactions, specifically, are known to dramatically reduce the electrical resistivity. Further, the change in the electrical resistivity of the binary Au—Cu alloys as they are thermally treated to transform from the disordered to the ordered state. In the disordered state, the resistivity is minimized at each of the pure metal states and gradually increases as the two elements are mixed, reaching a maximum near an equiatomic level. However, by heat treating the alloys within the appropriate time-temperature regime, it is possible to create an ordered phase and minimize the resistivity at both the 25 atomic percent and 50 atomic percent Au levels. The resistivity values vary in a linearly symmetric fashion as the composition is varied in either direction from the stoichiometric values. This behavior is the generally accepted model for order-disorder transitions. See Kuczynski, G. C., R. F. Hochman, and M. Doyama. “Study of the Kinetics of Ordering in the Alloy AuCu.” Journal of Applied Physics 26, no. 7 (July 1955): 871-78.

Palladium/copper alloy systems have also been subjects of technical papers and articles. A. Yu. Volkov, in “Improvements to the Microstructure and Physical Properties of Pd—Cu—Ag Alloys,” examined and reported on a range of compositions for the ternary alloy system. Volkov examined the effect of adding silver to a palladium-copper alloy with the primary focus on improving tensile strength. Although this work shows a positive impact on strength, as illustrated in Volkov, all the Ag additions also act to increase the resistivity, e.g., going to a resistivity of roughly 8.5 micro-ohm cm (20.3% IACS) for the Pd—Cu binary alloy going from a resistivity of roughly 11 micro-ohm cm (15.6% IACS) for an alloy with 12 atomic percent Ag. This work does not present any significant understanding regarding how to simultaneously optimize both the mechanical and electrical properties.

Additionally, U.S. Pat. No. 7,354,488 introduces the use of Re in conjunction with other elements such as B, Ni and Ru to increase the strength of high Pd content wrought alloys. In the absence of the synergistic influence of these complementary elements, the data suggests it takes Re levels of at least 10% to reach hardness levels over 300 HK. These alloys typically have very low electrical conductivity values in the 5-8% IACS level. In these systems where the Pd levels are usually above 75 wt %, the Re is thought to be a solid solution strengthening agent and not participate on a second phase or ordering reaction. Re is also occasionally used as a grain refining additive in dental casting alloys, but at very low concentrations, typically below 0.5%.

### SUMMARY

Embodiments disclosed herein are related to palladium-based ternary or higher alloys (“palladium alloys”), methods of manufacturing the palladium alloys, and apparatuses including the palladium alloys. In some embodiments, a palladium alloy is disclosed. The palladium alloy includes palladium at about 50-57 weight percent (“wt %”), copper at about 35-42 wt %, and silver at about 3-7 wt %. A heat-treated electrical conductivity of the palladium alloy exceeds 28% international annealed copper standard (“IACS”).

In some embodiments, the palladium is present at about 52.5 wt % to about 56 wt %, the copper is present at about 37-40 wt %, and the silver is present at about 5-6 wt %.

In some embodiments, rhenium is present at about 0.5-1.5 wt %.

In some embodiments, zinc is present at about 0.5-1.5 wt %.

In some embodiments, at least one of gallium or indium is present at about 0.5 to about 1.5 wt %.

In some embodiments, the palladium alloy includes at least one of tin, germanium, iron, or zirconium at about 0.5-1.5 wt %.

In some embodiments, the palladium alloy includes at least one of aluminum, manganese, ruthenium, gold, or boron at about 0.3-1.5 wt %.

In some embodiments, the palladium alloy includes boron at about 0.2 wt % or less.

In some embodiments, the palladium alloy is substantially free of platinum and cobalt.

In some embodiments, the heat-treated electrical conductivity of the palladium alloy is about 30-35% IACS.

In some embodiments, an ultimate tensile strength of the palladium alloy is about 1.1 GPa or greater.

In some embodiments, a yield strength of the palladium alloy is about 825 MPa or greater.

In some embodiments, a maximum current that may be carried by a wire of the palladium alloy exhibiting a diameter of 250 μm is 4.25 A or greater.

In some embodiments, a method of forming the palladium alloy. The method includes providing an initial palladium alloy, cold working the initial palladium alloy, annealing the initial palladium alloy at a temperature of about 650-850° C. to form an annealed palladium alloy, and age hardening the annealed palladium alloy for 16 hours or less to form the palladium alloy.

In some embodiments, the method includes providing an initial palladium alloy in the form of a wire exhibiting an initial diameter and cold working the initial palladium alloy includes drawing the wire one or more times until a final diameter of the wire is at least 70% less than the initial diameter.

In some embodiments, the method includes annealing the initial palladium alloy at a temperature of about 700-800° C.

In some embodiments, the method includes age hardening the annealed palladium alloy at a temperature of about 300-600° C.

In some embodiments, the method includes age hardening the annealed palladium alloy at a temperature of about 325-425° C.

In some embodiments, the method includes age hardening the annealed palladium alloy for less than 4 hours.

In some embodiments, the method includes age hardening the annealed palladium alloy for about 15 minutes to about 1 hour.

In some embodiments, a semiconductor test probe is disclosed including any of the palladium alloys disclosed herein.

In some embodiments, the semiconductor test probe is a wire.

In some embodiments, the semiconductor test probe is a cut from a foil.

Features from any of the disclosed embodiments may be used in combination with one another, without limitation. In addition, other features and advantages of the present disclosure will become apparent to those of ordinary skill in the art through consideration of the following detailed description and the accompanying drawings.

### BRIEF DESCRIPTION OF THE DRAWINGS

The drawings illustrate several embodiments of the present disclosure, wherein identical reference numerals refer to identical or similar elements or features in different views or embodiments shown in the drawings.

FIGS. 1A and 1B are graphs illustrating the effects silver has on the ultimate tensile strength and yield strength, respectively, of palladium-silver-copper alloys.

FIG. 2 is a graph illustrating the conductivity of palladium-copper alloys, some of which are alloyed with various atomic percentages of silver.

FIG. 3 is a graph illustrating the calculated effect that several alloying elements have on the heat treatment-annealed (“HTA”) conductivity and the potential conductivity of the alloy.

FIG. 4 is a graph illustrating the time required to age harden various palladium-based alloys at 380° C.

FIG. 5A is a table listing the compositions of several different palladium alloys.

FIGS. 5B-5F are tables listing the properties of the palladium alloys listed in FIG. 5A in the age hardened from annealed (“HTA”) and the age hardened from cold worked (“HTCW”) conditions.

FIG. 6A is a table listing the composition of five palladium alloys that are listed in FIGS. 6B and 6C.

FIGS. 6B and 6C are tables listing the conductivity (“% IACS”), tensile elongation (“TE”), 0.2% offset yield strength (“YS”), and ultimate tensile strength (“UTS”) of the palladium alloys listed in FIG. 6A.

FIG. 7 is a table illustrating the results of current stressed tensile test.

FIG. 8 is a table listing the results of stress relaxation tests.

FIG. 9A is a table listing the compositions of several different palladium alloys.

FIG. 9B is a table listing the physical properties of the palladium alloys shown in FIG. 9A.

FIG. 10 is a graph showing the conductivity (in % IACS) and yield strength (in ksi) for several different palladium alloys.

### DETAILED DESCRIPTION

Embodiments disclosed herein are related to palladium-based ternary or higher alloys (“palladium alloys”), methods of manufacturing the palladium alloys, and apparatuses including the palladium alloys. An example alloy includes a palladium-copper-silver alloy. Such an alloy may include palladium at about 50-57 weight percent (“wt %”), copper at about 35-42 wt %, and silver at about 3-7 wt %. The alloy may also include at least one of rhenium, zinc, gallium, indium, or any of the other elements disclosed herein. For instance, the alloy may include at least 0.5-2 wt % of at least one of rhenium, zinc, gallium, or indium. The alloy may exhibit at least one of a conductivity of 28% international annealed copper standard (“IACS”) or greater, an ultimate tensile strength of 1.1 GPa or greater, a yield strength of about 825 MPa or greater, or a maximum current that may be carried by a 250 μm wire of about 4 amperes (“A”) or greater.

It is noted that, as used in the Detailed Description, “palladium alloys” and the like (e.g., “palladium alloy”) refers to alloys that include palladium at about 50-57 weight percent (“wt %”), copper at about 35-42 wt %, and silver at about 7 wt % or less. Meanwhile, “palladium-copper alloys” and the like refer to palladium-copper alloys generically and, depending on context, may refer to palladium alloys (as defined above), alloys other than palladium alloys that likewise include palladium and copper, or both. Similarly, “palladium-copper-silver alloys” and the like refer to palladium-copper-silver alloys generically and, depending on context, may refer to palladium alloys (as defined above), alloys other than palladium alloys that likewise include palladium, copper, and silver, or both.

The palladium alloys may be used in a variety of applications. In an example, the palladium alloys may form test probes, such as semiconductor test probes fabricated from wire or foil form. In the field of test probes, as device sizes decrease, the discrete space on each device available for being contacted by electrical test probes also decreases. At the same time, the increased processing power requires that the test probes carry higher test currents and thereby accommodate higher test temperatures. The result of these requirements is that: 1) test probe cross-section must become smaller to ensure they can accurately be placed on the test pads, 2) the increase in test current coupled with the reduced probe cross-section creates the requirement for improved electrical conductivity of the test probe material to avoid the danger of probe overheating and failure, 3) as the test temperatures rise, the palladium alloys must exhibit good strength retention throughout the current rise sequence to avoid premature softening and failure during touch down and wipe, and 4) enhanced ductility is needed to allow extensive forming in the aged condition to ensure the tight dimensional tolerances needed in these miniature components.

Since power dissipation, or heating of the probe, is directly related to its electrical resistance, where:

power dissipated=probe current²×probe resistance

It is readily apparent that probe heating is directly proportional to its resistance, and that reducing the test probe's resistance or increasing its electrical conductivity is a critical means to allow the operation of smaller cross-section test probes at reasonable temperatures with increased current demands.

Moreover, in addition to lowering the bulk resistance of the wire or foil used to fabricate the probe, it is also imperative to maintain a low contact resistance during repeated touchdown of the probe on to the IC surface. This interfacial resistance is controlled by the normal force exerted on the probe at touchdown, the presence and nature of any surface films, and the degree of wipe imposed after initial contact. To ensure consistent performance, the probe design must ensure that the probe deflection remains in the elastic region through the test cycle. Therefore, under increased current density associated with using smaller cross-section probes, it is important that the probe not exceed its yield strength at elevated temperatures to prevent softening, gram force reduction and eventually premature failure.

Additionally, the alloys must resist any oxidation that could increase probe-device contact resistance. The oxidation resistance of noble metal alloys is well known, while the advantages of palladium-based noble metal alloys are universally recognized.

In view of these objectives, provided herein are palladium-based ternary or higher alloys which provide electrical conductivity of 28% IACS or greater, maintain hardness of 320 HK₁₀₀ or greater to provide wear resistance, and provide oxidation resistance. The palladium-based ternary or higher alloys exhibit a yield strength more than 825 MPa (120 ksi). Sufficient ductility in the fully age-hardened condition enables the palladium-based alloy to be formed into finished test probes or electrical contacts, while eliminating the need for post-forming age hardening, thus avoiding attendant risks of thermal distortion of precision formed shapes during said aging treatment. Other properties of the palladium alloys are discussed below.

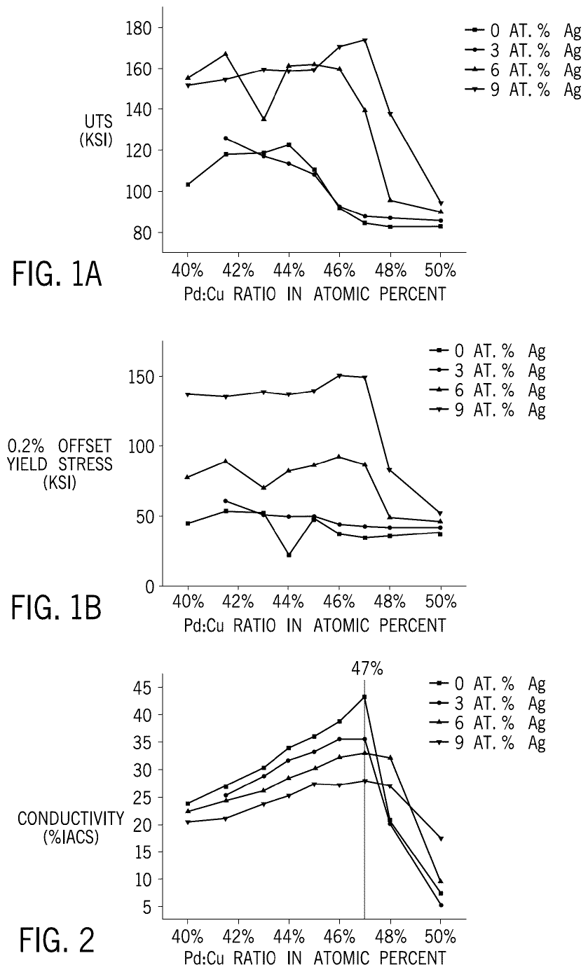

The palladium alloys are a palladium-copper-silver alloy. Palladium-copper-silver alloys have been used as semiconductor test probes. In palladium-copper-silver alloys, it is known that decreasing the silver content in the palladium-copper-silver alloy increases the conductivity of the palladium-copper-silver alloy (i.e., the palladium-copper binary exhibits the highest conductivity). However, decreasing the silver content in the palladium-copper-silver alloys comes with several costs, namely a decrease in the strength of the palladium-copper-silver alloy and increasing the age hardening time needed to use the palladium-copper-silver alloy as a semiconductor test probe. For example, FIGS. 1A and 1B are graphs illustrating the effects silver has on the ultimate tensile strength and yield strength, respectively, of palladium-silver-copper alloys. As shown in FIG. 1A, the palladium-copper-silver alloys barely exhibited an ultimate tensile strength greater than 160 ksi (1.1 GPa) when the alloy included silver at about 6 atomic percent (about 8 wt %) or higher. Similarly, as shown in FIG. 1B, the palladium-copper-silver alloys barely exhibited a yield strength greater than 75 ksi (515 MPa) and 120 ksi (825 MPa) when the alloy included silver at 6 atomic percent (about 8 wt %) or greater and 9 atomic percent (about 11 wt %), respectively. Further, it was believed that decreasing the silver content in the palladium-copper-silver alloys increased the time required for the age hardening process thereby making the manufacturing of palladium-copper-silver alloying including less than 8 wt % silver economically unviable. However, increasing the silver content of the palladium-copper-silver alloy above 8 wt % significantly decreased the time required to completely age harden the palladium-copper-silver alloy. As such, conventionally used palladium-copper-silver alloys included greater than 8 wt % silver to ensure that the palladium-copper-silver alloys exhibited sufficiently high strength and an aging process that was suitable for high output manufacturing even though the silver content of such palladium-copper-silver alloys decreased the conductivity of the palladium-copper-silver alloys.

The palladium alloys solve the above-described issues associated with conventional palladium-copper-silver alloys. In particular, the palladium alloys can exhibit a silver content that is less than 7 wt % (e.g., less than 6 wt %) thereby allowing the palladium alloys to exhibit a resulting higher conductivity. For example, the palladium alloys often exhibit a conductivity that is at least 20% greater than the best conducting alloy disclosed in U.S. Pat. No. 10,385,424 (“patent '424”) filed on Jan. 29, 2016, the disclosure of which is incorporated herein, in its entirety, by this reference. It has been found that adding elements to the palladium-copper-silver compositions of the palladium alloys and/or changes in the manufacturing process of the palladium alloys allow the palladium alloys to exhibit sufficiently high strength properties and make manufacture of the palladium alloys economically viable even though the palladium alloys exhibit low silver content.

### Alloy Compositions

The disclosed palladium alloys are palladium-based ternary or higher alloys. Alloying additions include copper (Cu) and silver (Ag). Other alloying elements that may be included in the palladium alloys are discussed below and may include, for example, rhenium (Re), zinc (Zn), indium (In), gallium (Ga), boron (B), aluminum (Al), ruthenium (Ru), tin (Sn), germanium (Ge), iron (Fe), zirconium (Zr), manganese (Mn), and gold (Au). In some cases, the palladium alloys may be free of or substantially free of one or more of the aforementioned alloying additions or elements.

Palladium may be present in the palladium alloys at about 50-57 wt %, about 51-56 wt %, about 52-56 wt %, about 52.5-55.5 wt %, about 51-53 wt %, about 52-54 wt %, about 53-55 wt %, about 54-56 wt %, about 52 wt %, about 53 wt %, about 54 wt %, or about 55 wt %.

Copper may be present in the palladium alloys at about 35-42 wt %, about 36-41 wt %, about 37-40 wt %, about 37-40.5 wt %, about 36-38 wt %, about 37-39 wt %, about 38-40 wt %, about 39-41 wt %, about 36 wt %, about 37 wt %, about 38 wt %, about 39 wt %, about 40 wt %, or about 41 wt %.

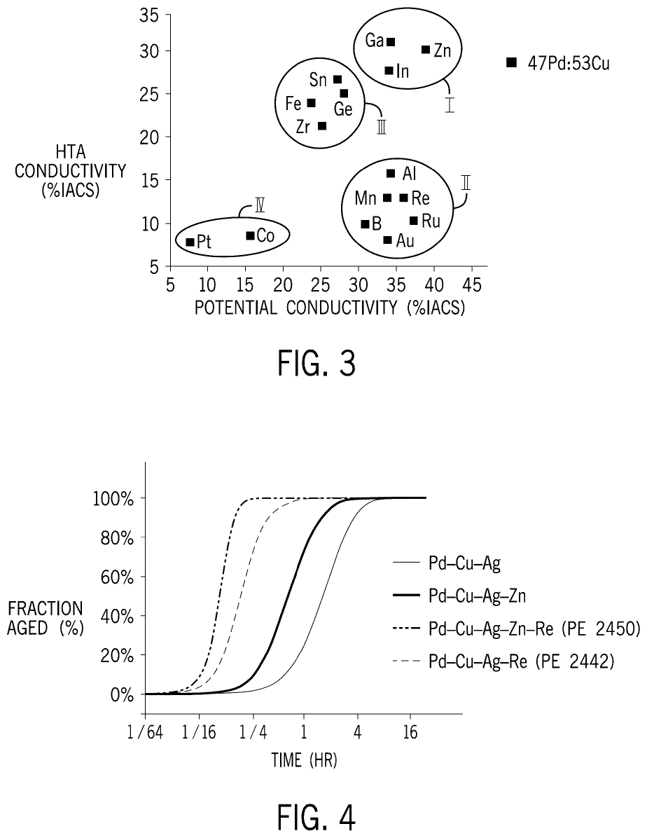

Silver may be present in the palladium alloys at about 3 wt % to 7 wt %, such as about 3 wt % to 6.5 wt %, about 3 wt % to 6 wt %, about 3 wt % to 5.7 wt %, about 3-5 wt %, about 4-6 wt %, about 5-7 wt %, about 3 wt %, about 4 wt %, about 5 wt %, about 6 wt % about 7 wt %. In some embodiments, the palladium alloys may include silver at about 7 wt % to less than 8 wt %. It is noted that it was conventionally believed that palladium-copper-silver alloys including less than 8 wt % silver (e.g., roughly 4.5 atomic percent silver depending on the quantity of palladium and copper in the alloy) and, more particularly 11 wt % silver (e.g., roughly 11 atomic percent silver depending on the quantity of palladium and copper in the alloy) prevented such palladium-copper-silver alloys from being used in certain applications, for instance in semiconductor test probes, due to the low yield strength thereof. For example, as shown in FIG. 2, only the palladium-copper-silver alloy including 9 atomic percent silver exhibited a yield strength greater than 120 ksi (825 MPa). In other words, it was conventionally believed that palladium-copper-silver alloys including a silver content less than 7 wt % would not exhibit a yield strength that is sufficient to be used in semiconductor test probes or other applications requiring a high yield strength. However, contrary to conventional knowledge, it has been found that the processes disclosed herein (discussed in more detail below) and/or the alloying additions disclosed herein allow the palladium alloys to exhibit a yield strength greater than 120 ksi (825 MPa) thereby allowing the palladium alloys to be used in semiconductor test probes or other applications requiring high yield strengths. It is noted that, in some embodiments, the palladium alloys may include silver at about 8 wt % to about 10 wt %.

In an embodiment, the palladium alloys exhibit a palladium to copper ratio in atomic percent (“Pd:Cu Ratio”). As used herein, the Pd:Cu Ratio is defined as:

$$\frac{{A}_{P d}}{{A}_{P d} + {A}_{C u}} * 100$$

where A_{Pd} is the atomic percent of palladium in the alloy and A_{Cu} is the atomic percent of copper in the alloy. The Pd:Cu Ratio is selected to about 48% or less, about 47% or less, about 40-48%, about 40-47%, about 43-47%, or about 44-47%. FIG. 2 is a graph illustrating the conductivity of palladium-copper alloys, some of which are alloyed with various atomic percentages of silver. As shown in FIG. 2, the conductivity of the palladium-copper alloy increases as the Pd:Cu Ratio increases until the Pd:Cu Ratio increases above 47%, at which the conductivity of the palladium-copper-silver alloys abruptly drops by about 30-50%. It is noted that increasing additives to the palladium-copper alloy decreases the drop in the conductivity of the palladium-copper-silver alloys as the Pd:Cu Ratio increases above 47%. For example, the conductivity of the palladium-copper alloy including no silver dropped by 51% when the Pd:Cu Ratio was increased from 47% to 48% while the conductivity of the palladium-copper alloy including 9 atomic percent silver dropped by less than 30% when the Pd:Cu Ratio was increased from 47% to 48%. It is currently believed that at least some of the other alloying components disclosed herein may be better than silver at minimizing (and may even prevent) the drop in conductivity as the Pd:Cu Ratio increases above 47%.

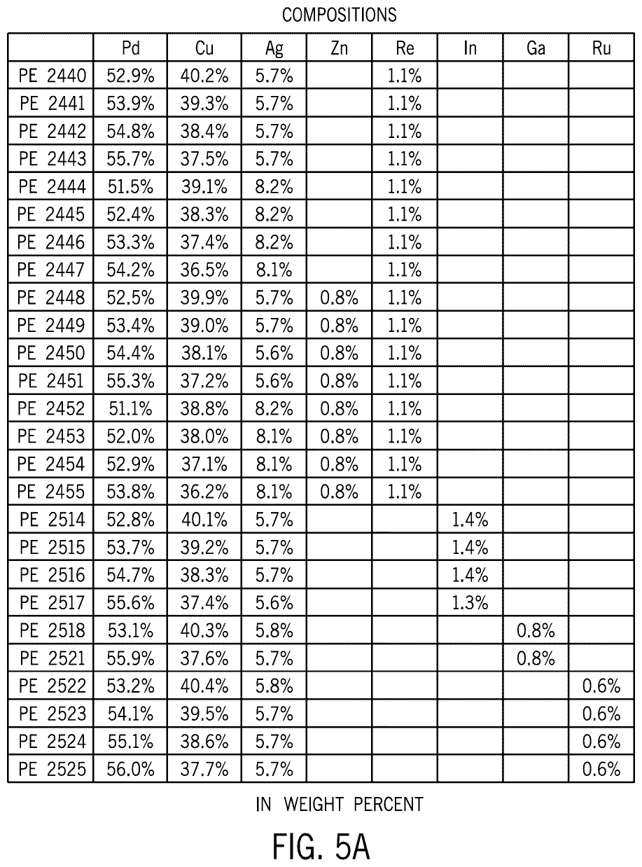

FIG. 3 is a graph illustrating the effect that several alloying elements have on the heat treatment from annealed (“HTA”) conductivity and the potential conductivity of the alloy. The potential conductivity is measured using an aging cycle that is industrially impractical and would likely adversely affect other properties of the alloys (e.g., strength or hardness) but was designed to reveal the potential conductivity of the alloy. The aging cycle was not optimized for each alloy so it the conductivity of the palladium alloys may be increased, for example, by as much as 5% IACS higher compared to the potential shown in FIG. 3. It is noted that HTA refers to the process of annealing (e.g., after cold working an initial alloy) and age hardening the palladium alloy, this process was designed to imitate industrially viable processes that are less likely to adversely affect other properties such as strength or hardness. The alloying elements, as shown in FIG. 3, form four distinct clusters, known herein as Cluster I elements, Cluster II elements, Cluster III elements, and Cluster IV elements.

Cluster I elements are the alloying elements that cause the palladium alloys to exhibit an HTA conductivity of about 27.5% IACS or greater and a potential conductivity of about 34% IACS or greater. The Cluster I elements include indium, gallium, and zinc. Alloying the palladium alloys to include Cluster I elements allow the alloy to achieve HTA conductivities near the alloy potential with industrially feasible processing. The actual conductivity (i.e., HTA conductivity) is greater than conventional palladium-copper-silver alloys (e.g., the palladium-copper-silver alloys disclosed in patent '424). Further, gallium and zinc also cause the palladium alloys to exhibit an actual conductivity that is greater than conventional palladium-copper-silver alloys by at least about 20%. Further, the Cluster I elements (including indium) gives the palladium alloys the potential to exhibit conductivity that is at least 30% greater than conventional palladium-copper-silver alloys when alloyed with certain elements and/or manufactured using specific processes.

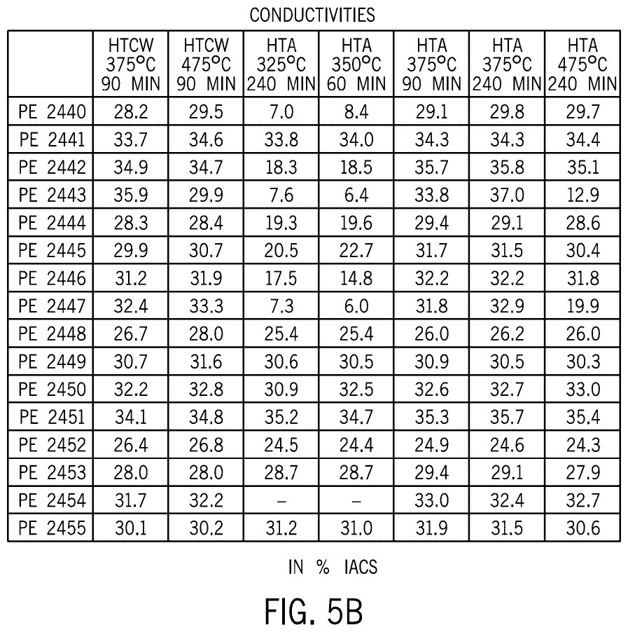

It has also been found that the Cluster I elements decrease the time required to fully age the palladium alloys. For example, FIG. 4 is a graph illustrating the time required to age harden various palladium-based alloys at 380° C. FIG. 4 illustrates that the palladium-copper-silver alloy that does not include any Cluster I elements (or rhenium) takes about 8 hours to completely age harden. However, about 1 wt % zinc alloyed into the palladium-copper-silver alloy decreases the aging time to less than 4 hours. In other words, zinc decreases the age hardening time by about a factor of 2. It is believed that gallium and indium similarly decrease the time required to completely age harden the palladium alloys. It has been found that Cluster I elements have a similar effect on the age hardening time even when the temperature of the age hardening process is changed.

The palladium alloys may include each Cluster I element or the Cluster I elements collectively at about 0.5-2 wt %, such as about 0.1-2 wt %, about 0.5-1.5 wt %, about 0.5-1 wt %, about 0.75-1.25 wt %, about 1-1.5 wt %, about 1.25-2 wt %, about 0.5 wt %, about 1 wt %, about 1.5 wt %, about 1.75 wt %, or about 2 wt %. The palladium alloys include 0.5 wt % or more of each Cluster I element or the Cluster I elements collectively so that the Cluster I element(s) have a non-negligible effect on the age hardening time and yield strength of the palladium alloy. The palladium alloys include 2 wt % or less of the Cluster I elements to prevent the Cluster I elements from forming detrimental grain boundaries structures, forming detrimental precipitates, or altering the desired ordering reaction of the palladium alloy. That said, in some embodiments, the palladium alloys may include each Cluster I element or the Cluster I elements collectively at less than 0.5 wt % or greater than 2 wt %. In some cases, the palladium alloys may be free of or substantially free of (e.g., less than 0.1 wt %) one or more of the Cluster I elements.

Cluster II elements are the alloying elements that cause the palladium alloys to exhibit an HTA conductivity of less than about 20% IACS and a potential conductivity of about 27.5% IACS or greater. In other words, Cluster II elements are elements that preserve the potential of the alloy to achieve a conductivity equal or greater than conventional palladium-copper-silver alloys disclosed in patent '424 but, do not achieve conductivities those conductivities using industrially viable practices. When alloyed into the palladium alloys with other alloying elements (e.g., Cluster I elements) or when used with specific manufacturing processes, the Cluster II elements can cause the palladium alloys to exhibit a conductivity that is greater than the conventional palladium-copper-silver alloys disclosed in patent '424. Cluster II elements may include aluminum, manganese, rhenium, ruthenium, boron, and gold. Other Cluster II elements not shown in FIG. 3 include rhodium. It is noted that the Cluster II elements may have similar effects on the age hardening time and the yield strength of the palladium alloys as the Cluster I elements. Cluster II elements have the potential to be used in conjunction with Cluster I elements to enhance other properties of the alloy such as strength while preserving the potential conductivity of the alloy.

The palladium alloys may include each Cluster II element or the Cluster II elements collectively at greater than 0 to about 2 wt %, such as about 0.1-2 wt %, about 0.5-2 wt %, such as about 0.5-1.5 wt %, about 0.5-1 wt %, about 0.75-1.25 wt %, about 1-1.5 wt %, about 1.25-2 wt %, about 0.5 wt %, about 1 wt %, about 1.5 wt %, about 1.75 wt %, or about 2 wt %. The palladium alloys include 2 wt % or less and, more preferably, less than 1.5 wt % or less of the Cluster II elements to minimize the detrimental effect the Cluster II elements have on the actual conductivity of the palladium alloys. That said, in some embodiments, the palladium alloys may include each Cluster II element or the Cluster II elements collectively at greater than 2 wt %. In some cases, the palladium alloys may be free of or substantially free of (e.g., less than 0.1 wt %) one or more of the Cluster II elements.

Cluster III elements are the alloying elements that cause the palladium alloys to exhibit an HTA conductivity of about 15-27.5% IACS and a potential conductivity of about 15-27.5% IACS. The Cluster III elements have less of an effect on the actual conductivity of the palladium alloys than the Cluster II elements but do not have the high potential conductivity of Cluster II elements. The Cluster III elements, when ignoring other alloying elements, cause the palladium alloys to exhibit a conductivity that is like the conventional palladium-copper-silver alloys disclosed in patent '424. Cluster III elements may include tin, germanium, iron, and zirconium. It is noted that the Cluster III elements may have similar effects on the age hardening time and the yield strength of the palladium alloys as the Cluster I elements.

The palladium alloys may include each Cluster III element or the Cluster III elements collectively at greater than 0 to about 2 wt %, such as about 0.1-2 wt %, about 0.5-2 wt %, about 0.5-1.5 wt %, about 0.5-1 wt %, about 0.75-1.25 wt %, about 1-1.5 wt %, about 1.25-2 wt %, about 0.5 wt %, about 1 wt %, about 1.5 wt %, about 1.75 wt %, or about 2 wt %. The palladium alloys include 2 wt % or less and, more preferably, less than 1 wt % of the Cluster III elements may minimize the detrimental effect the Cluster III elements have on the actual conductivity of the palladium alloys. That said, in some embodiments, the palladium alloys may include each Cluster III element or the Cluster III elements collectively at greater than 2 wt %. In some cases, the palladium alloys may be free of or substantially free of (e.g., less than 0.1 wt %) one or more of the Cluster III elements.

Cluster IV elements are the alloying elements that cause the palladium alloys to exhibit an HTA conductivity and a potential conductivity that is less than 15% IACS. As such, Cluster IV elements have a larger detrimental effect on the conductivity of the palladium alloys than either Cluster II elements or Cluster III elements. Cluster IV elements include platinum and cobalt. In an example, Cluster IV elements are omitted from the palladium alloys to prevent the detrimental effect that Cluster IV elements have on the conductivity of the palladium alloys. In an example, the palladium alloys may be substantially free of Cluster IV elements and may include small quantities of Cluster IV elements (e.g., less than 1 wt % and, more preferably, less than 0.5 wt %). For instance, the palladium alloys may include a small quantity of platinum to increase the nobility of the palladium alloys. In some cases, the palladium alloys may be free of one or more of the Cluster IV elements.

In a particular example, the palladium alloys include rhenium (a Cluster II element). In such an example, the alloy may include rhenium at 0.5-2 wt %, such as about 0.5-1 wt %, about 0.75-1.25 wt %, about 1-1.5 wt %, about 1.25-2 wt %, about 0.5 wt %, about 1 wt %, about 1.5 wt %, or about 2 wt %. It has been unexpectedly found that rhenium has a significant effect on the age hardening time of the palladium alloy while allowing the palladium alloy to exhibit a conductivity of 30% IACS or greater, especially when combined with Cluster I elements. For example, referring to FIG. 4, the palladium-copper alloys that include rhenium may decrease the age hardening time to less than 1 hour when the palladium-copper alloy is aged at 380° C. In other words, adding rhenium to the palladium alloys may decrease the age hardening time by a factor of about 8 compared to a palladium alloy that only includes palladium, copper, and silver. However, adding both rhenium and a Cluster I element to the palladium alloy decreases the age hardening time to about 15 minutes when the alloy is aged at 380° C. The decreased age hardening time caused by the rhenium addition to the palladium alloy allows for greater flexibility of the manufacturing process. For example, the decreased ageing time to achieve maximum conductivity caused by the rhenium addition allows for greater flexibility to optimize the aging process to achieve optimal combinations of strength and conductivity rather than forcing excessively long aging cycles to achieve conductivity that may adversely affect other properties such as strength.

In a particular example, the palladium alloys include boron (a Cluster II element). In such an example, the alloy may include boron at greater than 0 to about 0.2 wt %, such as 0 greater than 0 to about 0.1 wt %. It has been found that including such low quantities of boron in the palladium alloy increases at least one of the yield strength or ultimate tensile strength of the palladium alloy, especially when combined with rhenium. For example, such minor additions of boron in the palladium alloys may increase at least one of the yield strength or ultimate tensile strength by about 5-10%. It is noted that the boron additional may slightly slow the age hardening time of the palladium alloy compared to a palladium alloy that includes rhenium without the boron. However, as previously discussed, rhenium significantly decreases the age hardening time such that the effect of boron on the age hardening time of the palladium alloy is negligible from a manufacturing perspective. This is an example where the increase in aging rate in the HTA condition demonstrated by some elements such as Cluster I elements, Cluster III elements, and some Cluster II elements (e.g., rhenium) enable other elements, such as boron, to be added to improve other alloy properties such as strength.

It is noted that the palladium alloys may include other alloying elements other than those listed above. For example, the palladium alloys may include one or more impurities at about 0.05 wt % or less.

### Properties

Conductivity (IACS) exhibited by the palladium alloys, e.g., heat-treated palladium alloys, may be about 28% IACS or greater, such as about 28-30% IACS, about 29-31% IACS, about 30-32% IACS, about 30-35% IACS, about 31-33% IACS, about 32-34% IACS, about 33-35% IACS, about 34-36% IACS, or about 35-37% IACS. The conductivity of the palladium alloys may be measured using a 4-wire resistance test or eddy current conductivity tests. As previously discussed, the palladium alloys may be used in test probes. Electrical conductivity measurements may be performed using standard four-wire resistance measurement methodology, which provides accurate resistance measurements by eliminating contact resistance effects. The four-wire technique may involve applying a known current through outer probes while measuring voltage across inner probes, allowing for precise determination of bulk resistivity and subsequent calculation of electrical conductivity. Four-wire resistance measurements may be made on wire samples approximately 0.010 inches in diameter using a Keithley 7510 7.5 digit digital multimeter or equivalent instrumentation. Electrical conductivity measurements may also be performed by the use of an eddy current conductivity meter. Eddy current measurements may be performed on flat coupons with sizes ranging from approximately 1×1×0.05 inches to approximately 1.25×1.25×0.05 inches using a Verimet M4900X conductivity tester or equivalent instrumentation. Measurements may be made on both sides of the sample and averaged. Values are reported in the percent of the international annealed copper standard (% IACS). As previously discussed, the palladium alloys may be used in test probes. The size of such test probes is decreasing over time which, in turn, increases the current density and resistive heating of such test probes during use. The increased conductivity of the palladium alloys relative to conventional palladium-copper alloys allows the palladium alloys to be used in smaller test probes or at higher currents compared to conventional palladium-copper-silver alloys. The conductivity of the palladium alloys depends on one or more factors. For example, the conductivity of the palladium alloys increases as the fraction aged of the age hardening process increases and/or the quantity of silver in the palladium alloy decreases. The conductivity of the palladium alloys also depends on the annealing temperature with certain annealing temperature causing the palladium alloys to exhibit higher conductivities than other temperatures, as will be discussed in the Working Examples. The conductivity of the palladium alloys also depends on the Pd:Cu Ratio, as previously discussed.

A stress retention exhibited by the palladium alloys may be about 75% or greater and, more preferably, about 80% or greater when used in test probe applications. The stress retention is measured using 0.010 inch diameter straight wire that is bent into a 0.814 inch radius circle and held strained at 200° C. for 100 hours. As previously discussed, the palladium alloys may be used in test probes. During use, the test probes will be deflected by their contact with the wafer and held in the defected state for a period of time while subjected to increased temperature due to the ambient temperature of the testing machine and/or restive heating of the test probe. The test probe must maintain the mechanical stress to preserve the contact force on the wafer during testing otherwise incorrect test data may be generated. The stress retention depends, in part, on the process used to manufacture the palladium alloys.

A yield strength exhibited by the palladium alloys may be about 825 MPa or greater, such as about 850 MPa or greater, about 900 MPa or greater, about 950 MPa or greater, about 1000 MPa or greater, or in ranges of about 825-900 MPa, about 850-950 MPa, about 900-1000 MPa, about 950-1050 MPa, or about 1000-1100 MPa. As previously discussed, it was previously believed that the palladium alloys would be unable to exhibit such high yield strengths because decreasing the silver content below 8 wt % caused the yield strength of palladium-copper alloys to exhibit low yield strengths. However, contrary to conventional knowledge, it has been unexpectedly found that the palladium alloys can exhibit a yield strength of 825 MPa or greater, for example, due to the processing methods disclosed herein and/or the alloying additions disclosed herein. For instance, the decreased annealing temperatures disclosed herein increases the yield strength of the palladium alloy. It is currently believed that the decreased annealing temperature improves yield strength in the palladium alloys by reducing grain size of the palladium alloys, increasing the Hall-Petch contributions to the strength of the palladium allows, reducing age hardening temperature and age hardening times which inhibit over-aging of the palladium alloys, and/or reducing the frequency of anti-phase boundaries in the ordered phase of the palladium alloys.

The yield strength of the palladium alloys is related to the spring performance of the test probes formed thereby. For example, the test probes may need act as a spring within a significant elastic range. If the yield strength is too low (i.e., outside of the ranges disclosed above), the test probe will plastically bend instead of acting as a spring thereby resulting in failure. That said, the palladium alloys disclosed herein may exhibit a yield strength that are outside of the above disclosed ranges when used in test probes with less demanding requirements or used in other applications. The yield strengths disclosed herein may be measured using conventional tensile tests. Ultimate tensile strength and yield strength may be measured using conventional tensile tests on an Instron 3369 series test frame or equivalent instrumentation with a video extensometer to measure strain. Measurements of the yield strength may be reported as 0.2% offset yield strength in thousands of pounds per square inch (ksi) or megapascals (MPa).

An ultimate tensile strength exhibited by the palladium alloys may be about 1.1 GPa or greater, such as about 1.15 GPa or greater, about 1.2 GPa or greater, about 1.25 GPa or greater, about 1.3 GPa or greater, about 1.35 GPa or greater, or in ranges of about 1.1-1.2 GPa, about 1.15-1.25 GPa, about 1.2-1.3 GPa, or about 1.25-1.35 GPa. The ultimate tensile strength depends on several factors. For example, the ultimate tensile strength depends on the silver content of the palladium alloys, wherein increasing the silver content increased the ultimate tensile strength. It is noted that the ultimate tensile strength depends less on the silver content than the yield strength. Further, the method used to age the palladium (e.g., the temperature of the aging process) may also affect the ultimate tensile strength of the palladium alloy though, again, to a lesser extent than yield strength.

A max current exhibited by the palladium alloys (e.g., in a 250 μm diameter wire) may be about 4 A or greater, such as about 4.25 A or greater, about 4.5 A or greater, about 4.75 A or greater, or in ranges of about 4-4.5 A or about 4.25-4.75 A. As used herein, the max current refers to the current at which the yield stress of a 0.01 inch, or 250 μm, diameter wire falls below 90% of the maximum yield stress. Maximum currents of palladium alloy embodiments may be measured by tensile testing 0.010 inch diameter wire while simultaneously applying current to the wire. The maximum currents may be determined by comparing the tensile proof stress at 2%, 3%, 4%, and 5% elongation to the room temperature value and identifying where the proof stress consistently dropped below 90% of the room temperature value. The max current is related to both the conductivity of the palladium alloys (e.g., higher conductivity alloys generate less heat during use that may soften the alloy) and the alloys elevated temperature strength allowing the palladium alloys to preserve their strength in the presence of the resistive heating. Thus, the palladium alloys may exhibit a max current that is greater than at least some palladium-copper alloys, such as the palladium-copper-silver alloys disclosed in patent '424.

A hardness exhibited by the palladium alloys may be about 270 HK 100 or greater, such as about 280 HK₁₀₀ or greater, about 290 HK₁₀₀ or greater, about 300 HK₁₀₀ or greater, about 315 HK₁₀₀ or greater, about 330 HK₁₀₀ or greater, about 345 HK₁₀₀ or greater, about 360 HK₁₀₀ or greater, about 375 HK₁₀₀ or greater, about 390 HK₁₀₀ or greater, or in ranges of about 270-290 HK₁₀₀, about 280-300 HK₁₀₀, about 290-315 HK₁₀₀, about 300-330 HK₁₀₀, about 315-345 HK₁₀₀, about 330-360 HK₁₀₀, about 345-375 HK₁₀₀, or about 360-390 HK₁₀₀. Hardness measurements may be performed using a LECO LM247AT hardness tester, LECO M-400 hardness tester, or equivalent instrumentation with a 100 g load. Knoop indentation in the longitudinal direction near the center of the thickness of the cross-section. The hardness of the palladium alloys corresponds to the life span of the test probe formed from the palladium alloys. For example, the hardness of the palladium alloys corresponds to the ability of the test probes to maintain a sharp tip and resist wear during abrasive cleaning. The hardness of the palladium alloys may depend on several factors. For example, since the hardness of the palladium alloys is related to the yield and ultimate tensile strengths thereof, the hardness of the palladium alloys may depend on the same factors discussed above with regards to the yield and ultimate tensile strengths. Further, it has been found that the presence of rhenium, zinc, and other specific additives in the palladium alloys increases the hardness of the palladium alloys. Also, the hardness of the palladium alloys depends on the fraction aged of the age hardening process. It is noted that the hardness of the palladium alloys is greater than copper-silver alloys that do not include palladium.

As previously discussed herein, the processes disclosed herein improve the strength and hardness of the palladium alloys. However, these processes also decrease the tensile elongation and formability of the palladium alloys. As such, the processes disclosed herein may be configured to balance the increase in strength and hardness of the palladium with the tensile elongation and formability of the palladium alloys. That said, the palladium alloys disclosed herein, including the palladium alloys exhibiting any of the strengths and hardness disclosed above, may exhibit a maximum tensile elongation of about 10% or greater, about 15% or greater, about 20% or greater, about 25% or greater, about 30% or greater, about 35% or greater, about 40% or greater, or in ranges of about 10% to about 20%, about 15% to about 25%, about 20% to about 30%, about 25% to about 35%, about 30% to about 40%, or about 35% to about 45%. Tensile elongation measurements may be performed using conventional tensile tests on an Instron 3369 series test frame or equivalent instrumentation with a video extensometer to measure strain.

The palladium alloys may exhibit other properties. In an example, the palladium alloys may exhibit a Young's modulus of about 50 GPa or greater, about 75 GPa or greater, about 100 GPa or greater, about 125 GPa or greater or in ranges of about 50-300 GPa, about 75-250 GPa, or about 100-200 GPa. In an example, the palladium alloys may exhibit a temperature coefficient of resistance of less than about 1×10⁻²1/K or about 1×10⁻⁴-1×10⁻²1/K. In an example, the palladium alloys may exhibit a maximum ordered phase stability of 125-720° C. In an example, the palladium alloys may exhibit a dimensional tolerance of about 2 μm or less, such as 1-2 μm. In an example, the palladium alloys may exhibit a thermal conductivity of about 60-150 W/(m·K). In an example, the palladium alloys may exhibit an impact toughness of about 1-100 J/cm².

The maximum ordered phase stability of the palladium alloys may be characterized by the temperature required for the conductivity of the alloy to rapidly degrade. To determine the maximum ordered phase stability wires of 250 μm diameter in the cold worked condition were fully aged at approximately 400° C. then heated at a rate of 2° C. per minute up to 800° C. while measuring the 4-wire resistance at a twice per second. Tangent lines were calculated based on the linear increase in conductivity vs temperature observed below 500° C. and a second tangent line was calculated based on the point of most rapid increase in conductivity. The maximum ordered phase stability was calculated as the interception of these two tangent lines.

### Methods of Manufacture

An example method of manufacturing a palladium alloy using an HTA process is disclosed. It is noted that the HTA process may form a palladium alloy exhibiting one or more of the above-mentioned properties. For example, the HTA process can form a palladium alloy exhibiting a conductivity of 28% IACS or greater and a yield strength of about 825 MPa or greater.

The method includes providing an initial palladium alloy exhibiting any of the compositions disclosed herein. The initial palladium alloy may be formed using a conventional process for providing palladium-copper-silver alloys. For example, the palladium alloy may exhibit a melting temperature that is comparable to conventional palladium-copper-silver alloys thereby allowing the initial palladium alloy to be cast using conventional palladium-copper-silver casting processes.

The initial palladium alloy may be annealed, solutionized, or homogenized prior to initial cold work or may be cold worked directly depending on the casting parameters.

The initial palladium alloy may be cold worked. The initial palladium alloy may be cold worked using any suitable process. In an example, when the palladium alloy forms a wire, the cold working process may include drawing the initial palladium alloy in one or more steps to decrease the diameter of the wire. In an example, when the palladium alloy forms a foil, the cold working process may include decreasing the cross-sectional area or thickness of the foil using cold, warm, or hot rolling, or any other suitable technique. In either example, the cold working process may include reducing the diameter, cross-sectional area, or thickness of the initial palladium alloy until the diameter, cross-sectional area, or thickness is about 70% or more, about 75% or more, about 80% or more, about 85% or more, about 90% or more, about 95% or more, or in ranges of about 70% to about 80%, about 75% to about 85%, about 80% to about 90%, about 85% to about 95%, or about 90% to about 99% of the initial diameter. For instance, a final diameter of the wire is at least 70% less than the initial diameter, or less than about 75%, 80%, 85%, 90%, 95%, or 99% of the initial diameter. It has been surprisingly found that the cold working of the initial palladium alloy increases the strength of the final palladium alloy even though the palladium alloy is annealed after the cold working process.

Before the palladium alloy is age hardened, the initial palladium alloys may be annealed. For example, the initial palladium alloy may be annealed after cold working the palladium alloy.

The palladium alloy may be annealed at a temperature of about 650-950° C., such as in ranges of about 650-750° C., about 700-800° C., about 750-850° C., about 800-900° C., or about 850-950° C. It is currently believed that the decreased annealing temperature improves yield strength in the palladium alloys by reducing grain size of the palladium alloys, increasing the Hall-Petch contributions to the strength. The reduced aging times and/or temperatures due to the alloying additions preserve the finer grain structure of the alloy preserving the potential higher yield strength from annealing.

After annealing the palladium alloy, the palladium alloy may be cold worked again to increase the strength of the palladium alloy. However, it has been found that cold working the palladium alloy after annealing the palladium alloy only slightly increases the strength of the palladium alloy.

The annealed palladium alloy may be subjected to an age hardening process to increase the conductivity, strength, and hardness of the palladium alloy. The age hardening process may include heating the annealed palladium alloy to a temperature of about 300-600° C., such as about 300-350° C., about 325-375° C., about 325-425° C. about 350-400° C., about 375-425° C., about 400-450° C., about 425-475° C., or about 450-500° C. The time during which the palladium alloy is age hardened should be selected such that the fraction aged of the palladium alloy is at least 95%. The time period may be about 5 minutes or greater, about 15 minutes or greater, about 30 minutes or greater, about 45 minutes or greater, about 60 minutes or greater, about 75 minutes or greater, about 90 minutes or greater, about 2 hours or greater, about 3 hours or greater, about 4 hours, less than 4 hours, or greater than 4 hours, about 5 hours or greater, about 6 hours or greater, about 8 hours or greater, about 12 hours or greater, about 16 hours or greater, or in ranges of about 5-30 minutes, about 15-45 minutes, about 30-60 minutes, about 45-75 minutes, about 60-90 minutes, about 75 minutes to about 2 hours, about 15 minutes to 1 hour, about 1.5-3 hours, about 2-4 hours, about 3-5 hours, about 4-6 hours, about 5-7 hours, about 6-8 hours, about 7-12 hours, or about 8-16 hours. The age hardening temperature and time may be selected based on a number of factors. In an example, the age hardening temperature may be selected based on the time or vice versa since the age hardening temperature and time are interrelated. For instance, increasing the age hardening temperature allows the time to be decreased. In an example, the age hardening temperature and time may be selected based on the composition of the palladium alloy. For instance, increasing the silver content, the Cluster I element(s) content, rhenium content, or other selected elements in the palladium alloy allows the age hardening temperature and/or time to be decreased, oftentimes significantly decreased.

It is noted that the palladium alloys may be formed using processes other than the HTA process disclosed above. For example, the palladium alloys may be formed using an age hardening cold working (“HTCW”) process. The HTCW process includes cold working the initial palladium alloy and then subjecting the palladium alloy to an age hardening process without the intervening annealing process. The cold working and age hardening of the HTCW process may be substantially like the cold working and age hardening process of the HTA The HTCW process may form palladium alloys exhibiting higher hardness and strength than the palladium alloys formed using the HTA process. However, the HTCW process may result in palladium alloys including significant residual stresses which may make achieving geometric tolerances such as straightness for wire or flatness for foil difficult. The HTCW process may also form palladium alloys exhibiting poor tensile elongation and formability. In an example, the palladium alloys may be formed using the processes disclosed in patent '424.

### WORKING EXAMPLES

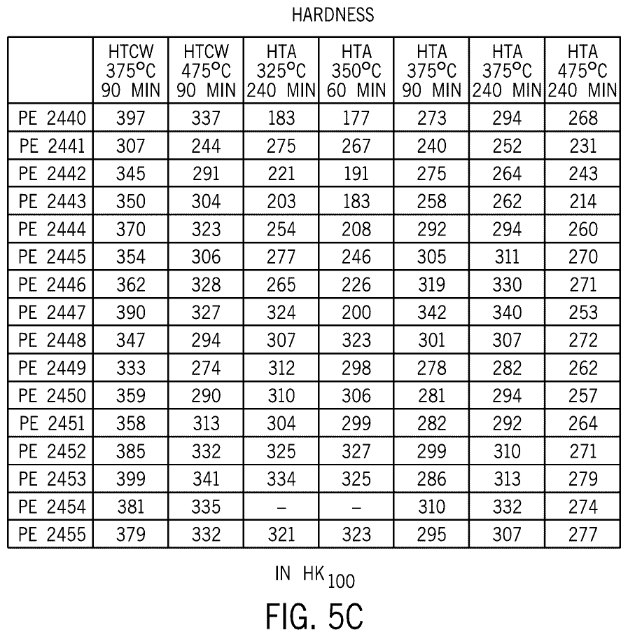

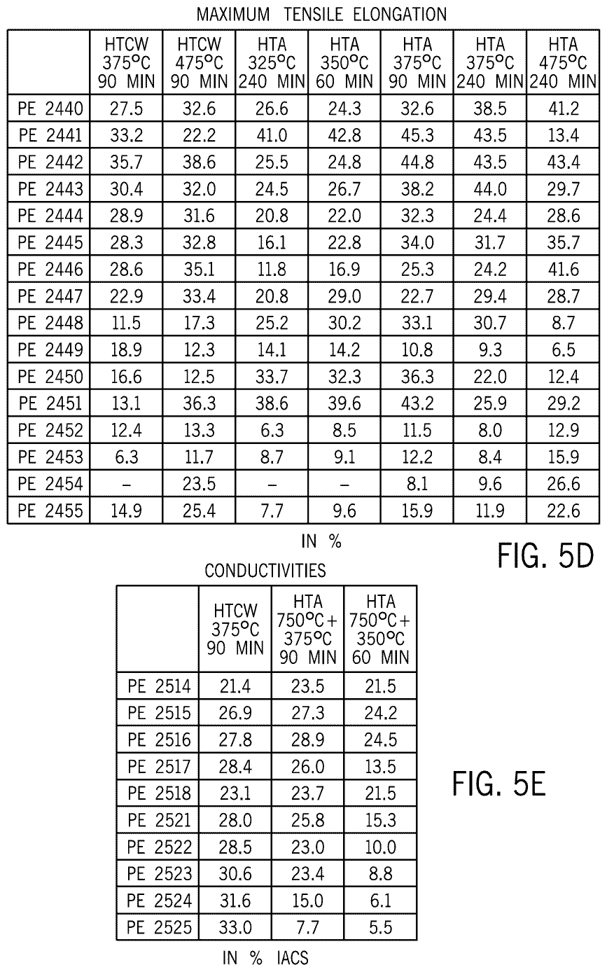

FIG. 5A is a table listing the compositions of several different palladium alloys. FIGS. 5B-5F are tables listing the properties of the palladium alloys listed in FIG. 5A. The methods used to form each of the alloys discussed in FIGS. 5B-5E are listed at the top of each column.

FIG. 5B lists the conductivity of several palladium alloys that include rhenium and, optionally, zinc manufactured using a variety of processes. As shown in FIG. 5B, the conductivity of the palladium alloys depends on the composition of the palladium alloys and the process used to manufacture the palladium alloys. It is noted that the conductivity of most of the palladium alloys formed using the HTA process are above 28% IACS when the age hardening process is at or above 375° C. It is also noted that the palladium alloys exhibiting lower silver content exhibits a conductivity that is greater than the palladium alloys exhibiting higher silver content.

FIG. 5C lists the hardness (in HK₁₀₀) of several palladium alloys that include rhenium and, optionally, zinc manufactured using a variety of processes. As shown in FIG. 5C, the hardness of the palladium alloys depends on the composition of the palladium alloys and the process used to manufacture the palladium alloys. FIG. 5C demonstrates that the HTCW palladium alloys exhibit a higher hardness than the HTA palladium alloys and that palladium alloys including higher silver contents exhibit a higher hardness than palladium alloys with lower silver content. However, regardless of the manufacturing process and the silver content of the palladium alloys, many of the palladium alloys exhibit a hardness that is satisfactory for test probe applications.

FIG. 5D lists the maximum tensile elongation of several palladium alloys that include rhenium and, optionally, zinc manufactured using a variety of processes. As shown in FIG. 5D, the maximum tensile elongation of the palladium alloys depends on the composition of the palladium alloys and the process used to manufacture the palladium alloys. FIG. 5D demonstrates that the HTCW palladium alloys exhibit a lower tensile elongation than the HTA palladium alloys and that palladium alloys including higher silver contents exhibit a lower tensile elongation than palladium alloys with lower silver content.

FIG. 5E lists the conductivity (in % IACS) of several palladium alloys that include indium, gallium, and ruthenium. FIG. 5E demonstrates that several of these palladium alloys exhibit a conductivity that is greater than 28% IACS. However, like the palladium alloys including rhenium and zinc, the conductivity of the palladium alloys including indium, gallium, and ruthenium depend on the composition of the palladium alloys and the manufacturing process.

FIG. 5F lists the physical properties of several palladium alloys that include indium, gallium, and ruthenium. The palladium alloys listed in FIG. 5F were manufactured using an HTCW process that included age hardening the palladium alloys at 375° C. for 90 minutes. FIG. 5F demonstrates that several of these palladium alloys exhibit a hardness, tensile elongation, yield strength, and ultimate tensile strength that are sufficiently high to be used in test probe applications.

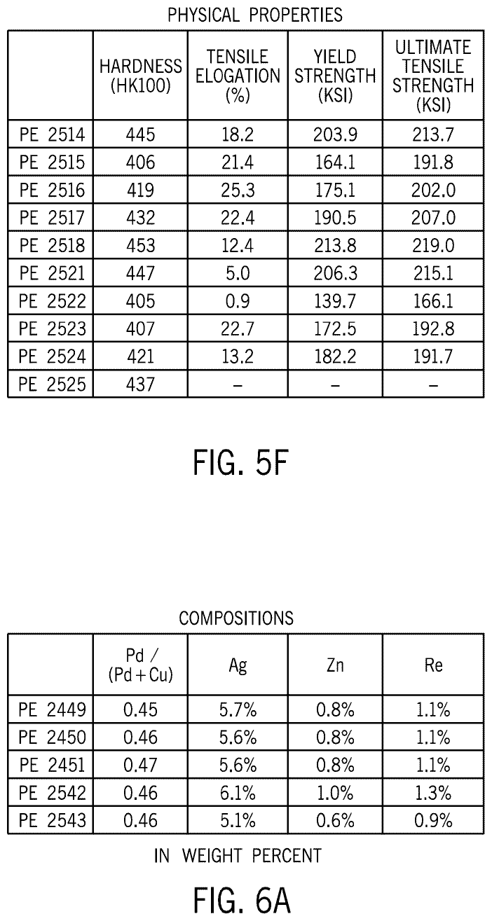

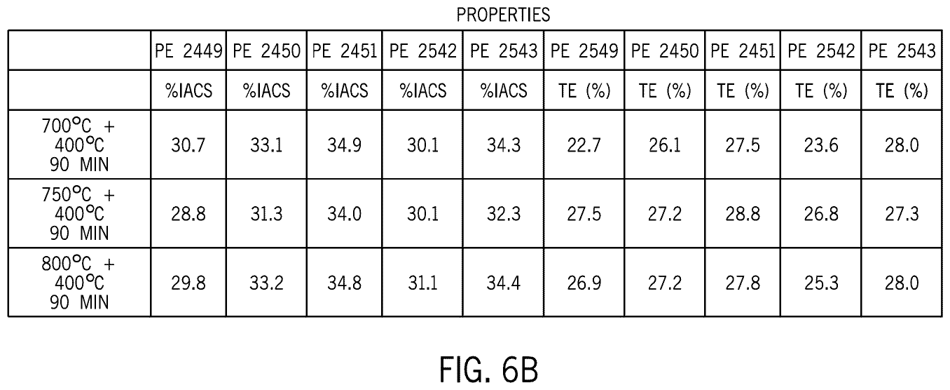

FIG. 6A is a table listing the composition of five palladium alloys that are discussed in FIGS. 6B and 6C. FIGS. 6B and 6C are tables listing the properties of the palladium alloys listed in FIG. 6A. Each of the palladium alloys listed in FIG. 6A were drawn to a diameter of 0.003 inches. Each of the five palladium alloys were then annealed and age hardened using three different annealing processes shown on the right side of FIGS. 6B and 6C. As shown in FIGS. 6B and 6C, each of the five palladium alloys manufactured at each of the three processes exhibited a conductivity of about 29-35% IACS and a maximum tensile elongation, yield strength, and ultimate tensile strength that is sufficient for use in test probe applications. It is noted that the yield strength ranged from 123 to 165 ksi depending on the annealing process indicating that the yield strength depends on the annealing process.

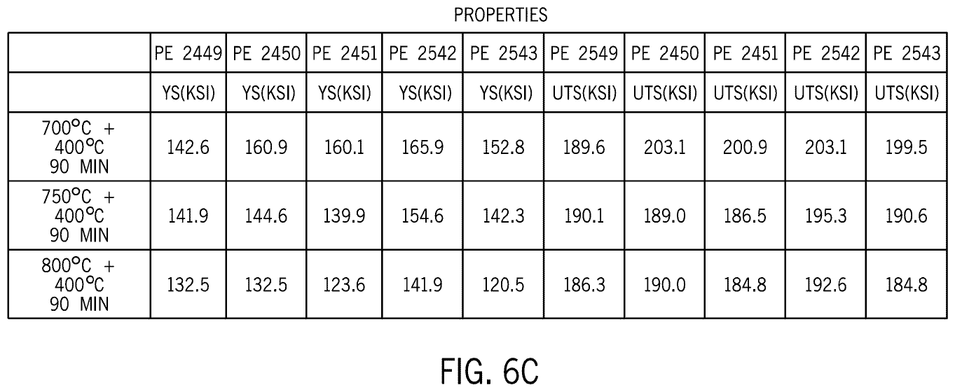

It is noted that the five palladium alloys listed in FIG. 7A were also age hardened at 325° C. for 240 minutes and 350° C. for 60 minutes. The five palladium alloys manufactured using these processes showed incomplete aging characteristics and low conductivity, thereby demonstrating that the conductivity depends on age hardening process and, in particular, the fraction aged of the palladium alloys.

Conventional palladium-copper-silver alloys (e.g., the palladium-copper-silver alloys disclosed in patent '424) suffered from reduced ability to localize stress resulting in lower-than-expected bend performance based on tensile ductility. To determine if the palladium alloys suffer similar issues, bend testing was performed on PE-2450 palladium alloy, the composition of which is provided in FIGS. 5A and 6A. The test included providing PE-2450 palladium alloy wires exhibiting a 0.010 inch diameter manufactured using four different processes. The four processes consisted of an HTCW process including age hardening the alloy at 400° C. for 1.5 hours, an HTA process including annealing the alloy at 700° C. and age hardening the alloy at 350° C. for 1 hour, an HTA process including annealing the alloy at 750° C. and age hardening the alloy at 350° C. for 1 hour, and an HTA process including annealing the alloy at 800° C. and age hardening the alloy at 350° C. for 1 hour. Each wire was then doubled up and drawn through a 0.020 inch diameter die to form a 180° bend and force inside bend radius (R) to be as low as possible resulted in a radius/thickness (R/t) of 0 in the wire. Each of the PE-2450 palladium alloy wires passed the bend test indicating that the palladium alloys exhibit better bend formability compared to conventional palladium-copper-silver alloys, which is relevant for many secondary applications such as cantilever probes or sliding electrical contact applications.

PE-2449, PE-2450, and PE-2451 palladium alloy wires exhibiting a 0.01 inch diameter were subjected to a current stressed tensile test. Each of the compositions of palladium alloy wires were manufactured using four processes, namely an HTA process including annealing the alloy at 700° C. and age hardening the alloy at 350° C. for 1 hour, an HTA process including annealing the alloy at 750° C. and age hardening the alloy at 350° C. for 1 hour, an HTA process including annealing the alloy at 800° C. and age hardening the alloy at 350° C. for 1 hour, and an HTCW process including age hardening the alloy at 400° C. for 1.5 hours. The test included determining the engineering stress-strain curve for each of these wires while a set current was flowed through the wires. The palladium alloy wires were determined to pass the test at a given current if the yield strength of the wires was without 90% of the yield strength of the palladium wires without a current flowing through the wires. FIG. 7 is a table illustrating the results of the current stressed tensile test. FIG. 7 demonstrates that each of the wires were able to have a maximum current of 4.25 A flow therethrough and each of the wires processed using the HTA process were able to have a maximum current of 4.5 A or 4.75 A flow therethrough.

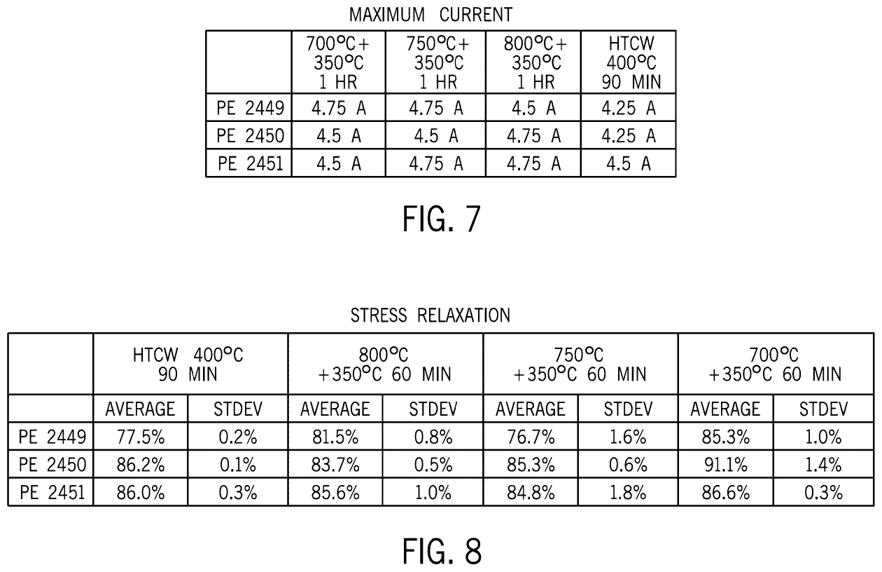

PE-2449, PE-2450, and PE-2451 palladium alloy wires exhibiting a 0.01 inch diameter were subjected to a stress relaxation test. Each of the compositions of palladium alloy wires were manufactured using four processes, namely an HTCW process including age hardening the alloy at 400° C. for 1.5 hours, an HTA process including annealing the alloy at 700° C. and age hardening the alloy at 350° C. for 1 hour, an HTA process including annealing the alloy at 750° C. and age hardening the alloy at 350° C. for 1 hour, and an HTA process including annealing the alloy at 800° C. and age hardening the alloy at 350° C. for 1 hour. The wires were processed such that they were straight after annealing. The straight wires were bent into a circle with a 0.8 inch radius imposing a bending stress of 100-120 ksi on the wire and fixed into position using a fixture. The bent wires were loaded into a convection oven and held at 200° C. for 100 hours. The wires were removed from the fixture and allowed to spring back to their new unloaded shape, and the resulting radius of curvature of the wires were measured. The amount of the initial 100-120 ksi bending stress that had relaxed during testing was calculated based on the final radius of curvature (e.g., a wire that recovered its original straight shape would have 100% stress retention and a wire that retained the bent circular shape of the fixture after removal would have 0% stress retention). FIG. 8 is a table listing the results of the stress relaxation tests. FIG. 8 demonstrates that the stress retained in the palladium alloy wires, when compared to FIG. 6C, was only weakly correlated to the yield strength of the palladium alloy. FIG. 8 also demonstrates that the palladium wires processed using the HTA process surprisingly exhibited higher stress retention than the palladium wires processed using the HTCW process.

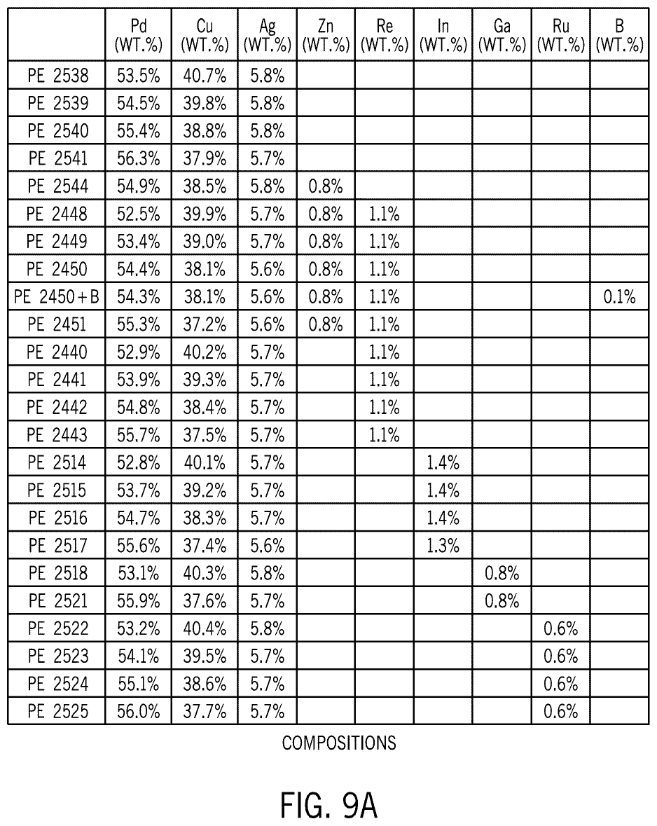

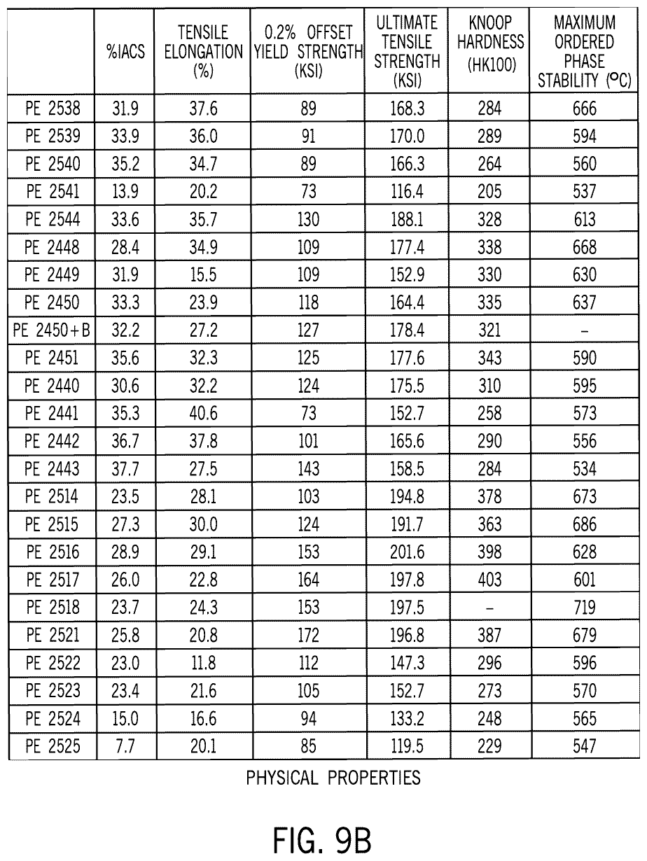

FIG. 9A is a table listing the compositions of several different palladium alloys. Each of the palladium alloys listed in FIG. 9A were drawn to a 0.010 inch diameter wire, then annealed at 750° C., and then age hardened at 400° C. FIG. 9B is a table listing the physical properties of the palladium alloys shown in FIG. 9A. FIG. 9B demonstrates that most of the alloys exhibit a conductivity that is comparable to or exceeds the conductivity of conventional palladium-copper-silver alloys, namely a conductivity comparable to or greater than 20% IACS. Most of the palladium alloys shown in FIG. 9B exhibit a conductivity greater than 28% IACS and several of the palladium alloys exhibit a conductivity greater than 30% IACS or greater than 32% IACS. Further, most of the palladium alloys including at least one of zinc, rhenium, indium, gallium, ruthenium, boron or other Cluster I, II, and/or III elements exhibit physical properties that are sufficient for at least some test probe applications. For example, most of these palladium alloys exhibit a yield strength greater than 100 ksi, with some of these palladium alloys exhibiting a yield strength greater than 125 ksi. However, the ternary palladium-copper-silver alloys do not exhibit physical properties that allow these ternary palladium-copper-silver alloys to be used in test probe applications. In particular, the yield strength of these ternary palladium-copper-silver alloys is too low for test probe applications.

It is noted that FIG. 9B lists the maximum ordered phase stability of the palladium alloys listed in FIG. 9A. The maximum ordered phase stability of the palladium alloys is generally the maximum operating temperature of the palladium alloys. At temperatures above the maximum ordered phase stability, the palladium alloys begin to undergo a disordering reaction. The disordering reaction may cause test probes including the palladium alloys to, during use, experience “runaway” resistive heating temperatures that results in failure of the palladium alloys. For example, the disordering reaction increases the resistivity of the palladium alloys. The increases resistivity of the palladium alloys causes the temperature of the test probes to increases as a current flowing through the test probes remains constant. The increased temperature of the test probes further increases the disordering reaction, causing the resistivity of the palladium alloys to increase even more which in turn, increases the temperature of the test probes even more. This cycle continues, often rapidly, until the test probes fail. FIG. 9B demonstrates that the palladium alloys including at least one of zinc, rhenium, indium, gallium, ruthenium, or boron exhibit a maximum ordered phase stability that is comparable and, in many cases, greater than the maximum ordered phase stability of the ternary palladium-copper-silver alloys. FIG. 9B also illustrates that the palladium alloys may exhibit a maximum ordered phase stability of about 525-725° C., about 550-700° C., about 600-725° C., or about 600-700° C.

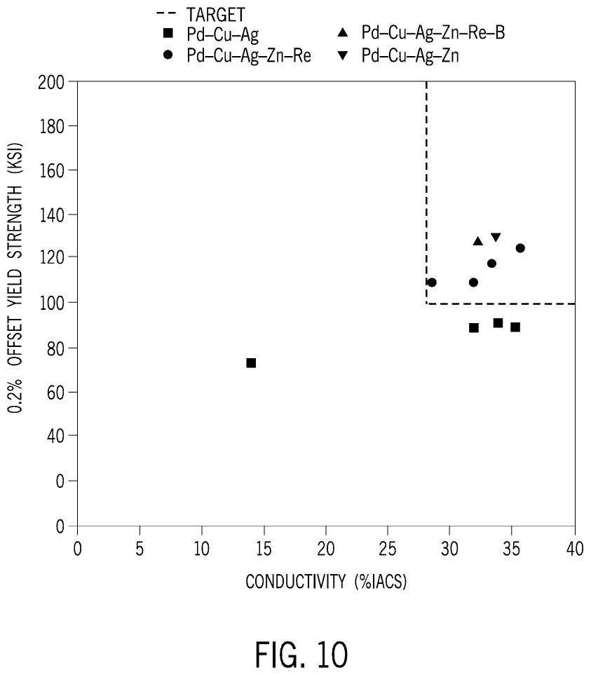

FIG. 10 is a graph showing the conductivity (in % IACS) and yield strength (in ksi) for several different palladium alloys. The palladium alloys shown in FIG. 10 were drawn to a 0.010 inch diameter wire, then annealed at 750° C., and then age hardened at 400° C. FIG. 10 demonstrates that the palladium alloys including at least one of zinc, rhenium, or boron exhibit conductivities greater than 28% IACS and a yield strength greater than 100 ksi whereas palladium-copper-silver ternary alloys do not exhibit this combination of properties.

While various aspects and embodiments have been disclosed herein, other aspects and embodiments are contemplated. The various aspects and embodiments disclosed herein are for purposes of illustration and are not intended to be limiting.

Terms of degree (e.g., “about,” “substantially,” “generally,” etc.) indicate structurally or functionally insignificant variations. In an example, when the term of degree is included with a term indicating quantity, the term of degree is interpreted to mean±10%, +5%, or +2% of the term indicating quantity. In an example, when the term of degree is used to modify a shape, the term of degree indicates that the shape being modified by the term of degree has the appearance of the disclosed shape. For instance, the term of degree may be used to indicate that the shape may have rounded corners instead of sharp corners, curved edges instead of straight edges, one or more protrusions extending therefrom, is oblong, is the same as the disclosed shape, etc. The term “substantially free of” means less than 0.1 wt %, less than 0.01 wt %, less than 0.001 wt % of the component or element or encompasses trace amounts of components or elements that do not otherwise affect the material properties of the alloy.

What is claimed is:

1. A palladium-based ternary or higher alloy (“palladium alloy”), comprising:
palladium at about 50-57 wt %;
copper at about 35-42 wt %; and
silver at about 3-7 wt %;
wherein a heat-treated electrical conductivity of the palladium alloy exceeds 28% international annealed copper standard (“IACS”).

2. The palladium alloy of claim 1, wherein the palladium is present at about 52.5 wt % to about 56 wt %, the copper is present at about 37-40 wt %, and the silver is present at about 5-6 wt %.

3. The palladium alloy of claim 1, further comprising rhenium at about 0.5-1.5 wt %.

4. The palladium alloy of claim 1, further comprising zinc at about 0.5-1.5 wt %.

5. The palladium alloy of claim 1, further comprising at least one of gallium or indium at about 0.5 to about 1.5 wt %.

6. The palladium alloy of claim 1, further comprising at least one of tin, germanium, iron, or zirconium at about 0.5-1.5 wt %.

7. The palladium alloy of claim 1, further comprising at least one of aluminum, manganese, ruthenium, gold, or boron at about 0.3-1.5 wt %.

8. The palladium alloy of claim 1, further comprising boron at about 0.2 wt % or less.

9. The palladium alloy of claim 1, wherein the palladium alloy is substantially free of platinum and cobalt.

10. The palladium alloy of claim 1, wherein the heat-treated electrical conductivity of the palladium alloy is about 30-35% IACS.

11. The palladium alloy of claim 1, wherein an ultimate tensile strength of the palladium alloy is about 1.1 GPa or greater.

12. The palladium alloy of claim 1, wherein a yield strength of the palladium alloy is about 825 MPa or greater.

13. The palladium alloy of claim 1, wherein a maximum current in a wire of the palladium alloy exhibiting a diameter of 250 μm is 4.25 A or greater.

14. A method of forming the palladium alloy of claim 1, the method comprising:
providing an initial palladium alloy;
cold working the initial palladium alloy;
annealing the initial palladium alloy at a temperature of about 650-850° C. to form an annealed palladium alloy; and
age hardening the annealed palladium alloy for 16 hours or less to form the palladium alloy.

15. The method of claim 14, wherein annealing the initial palladium alloy includes annealing the initial palladium alloy at a temperature of about 700-800° C.

16. The method of claim 14, wherein age hardening the annealed palladium alloy includes age hardening the annealed palladium alloy at a temperature of about 300-600° C. or at a temperature of about 325-425° C.

17. The method of claim 14, wherein age hardening the annealed palladium alloy includes age hardening the annealed palladium alloy for less than 4 hours.

18. A semiconductor test probe including the palladium alloy of claim 1.

19. The semiconductor test probe of claim 18, wherein the semiconductor test probe is a fabricated from a wire.

20. The semiconductor test probe of claim 18, wherein the semiconductor test probe is a fabricated from a foil.
